(19) United States
(12) Patent Application Publication
(10) Pub. No.: US 2008/0225472 A1
(43) Pub. Date: Sep. 18, 2008

(54) DUAL DISPLAY DEVICES

(75) Inventor: Ting-Hui Chih, Hualien (TW)

Correspondence Address: QUINTERO LAW OFFICE, PC, 2210 MAIN STREET, SUITE 200, SANTA MONICA, CA, 90405, US

(73) Assignee: QISDA CORPORATION, TAOYUAN COUNTY (TW)

(21) Appl. No.: 12/044,859

(22) Filed: Mar. 7, 2008

(30) Foreign Application Priority Data
Mar. 13, 2007 (TW) TW96108574

(51) Int. Cl. H05K 5/00; A47B 46/00; H05K 7/00

(52) U.S. Cl. 361/681; 248/349.1

(57) ABSTRACT

Dual display devices are provided. A dual display device includes a first display, a second display, a support, a rotary mechanism, and a translation mechanism. The rotary mechanism is pivotally connected to the support and coupled with the first and second displays, wherein the first and second displays are synchronously rotated with respect to the support via the rotary mechanism. The translation mechanism is movably connected to the support and coupled with the rotary mechanism, wherein the first and second displays are symmetrically moved with respect to the support via the translation mechanism.

### BACKGROUND OF THE INVENTION

1. Field of the Invention

The invention relates in general to dual display devices and in particular to dual display devices capable of rotation and translation.

2. Description of the Related Art

Various rotary mechanisms have been applied for conventional flat displays for angle adjustment. With respect to special and complex mechanisms for dual display devices, designing posture adjustment mechanisms of the displays has become a significant challenge.

### BRIEF SUMMARY OF THE INVENTION

Dual display devices are provided. A dual display device includes a first display, a second display, a support, a rotary mechanism, and a translation mechanism. The rotary mechanism is pivotally connected to the support and coupled with the first and second displays, wherein the first and second displays are synchronously rotated with respect to the support via the rotary mechanism. The translation mechanism is movably connected to the support and coupled with the rotary mechanism, wherein the first and second displays are symmetrically moved with respect to the support via the translation mechanism.

### BRIEF DESCRIPTION OF THE DRAWINGS

The invention can be more fully understood by reading the subsequent detailed description and examples with references made to the accompanying drawings, wherein:

FIG. 1 is a perspective diagram of a dual display device according to an embodiment of the invention;

FIGS. 2-6 are perspective diagrams of a first display and a second display capable of rotation and translation according to an embodiment of the invention;

FIG. 7 is a top view of the dual display in FIG. 1; and

FIG. 8 is a sectional view along A-A′ in FIG. 1.

### DETAILED DESCRIPTION OF THE INVENTION

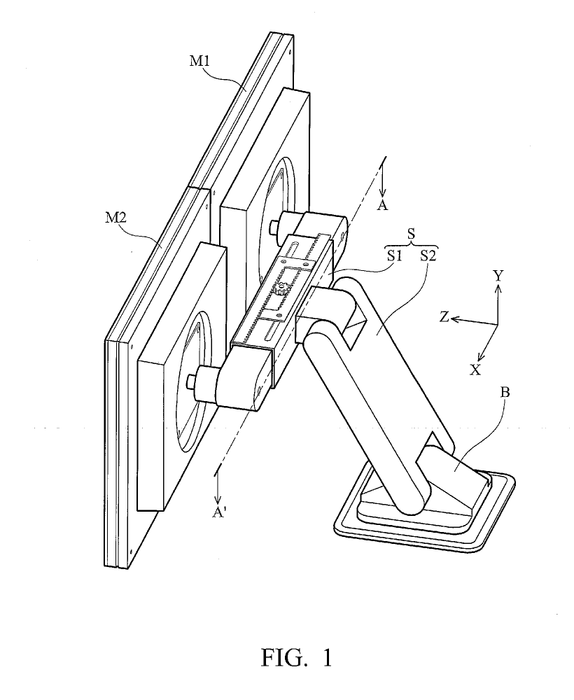

Referring to FIG. 1, an embodiment of a dual display device according to the invention primarily comprises a first display M1, a second display M2, a support S, and a base B. The support S is pivotally connected to the base B for sustaining the first and second displays M1 and M2. As shown in FIG. 1, the support S comprises a frame S1 and a connection member S2 pivotally connecting the base B and the frame S1, such that the first and second displays M1 and M2 are rotatable around X axis for angle adjustment.

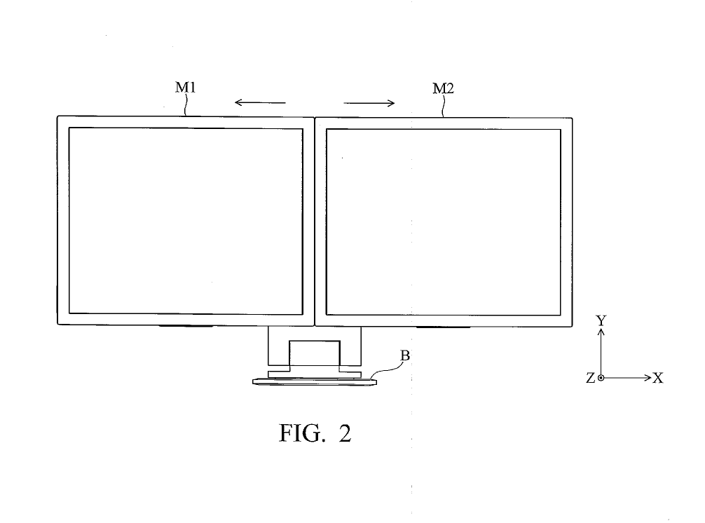

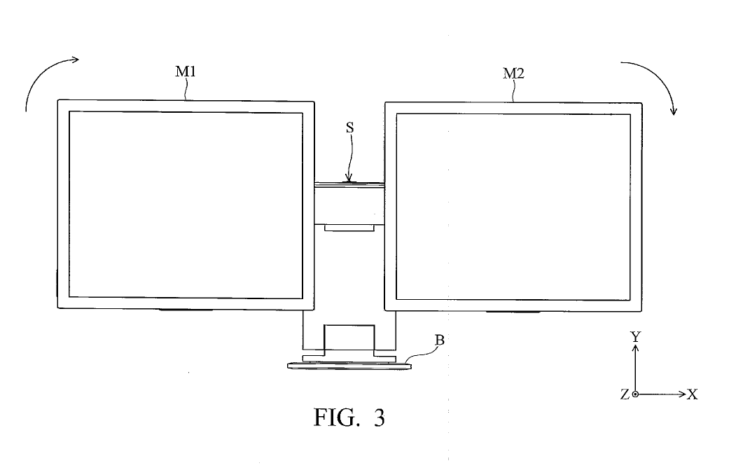

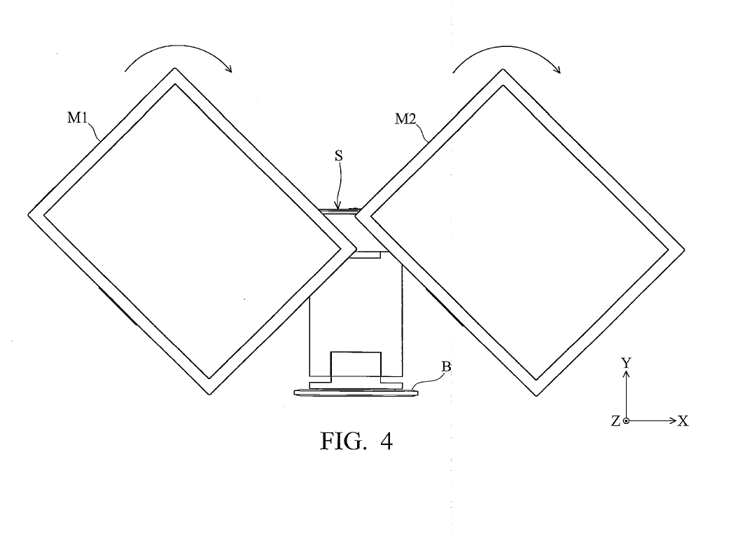

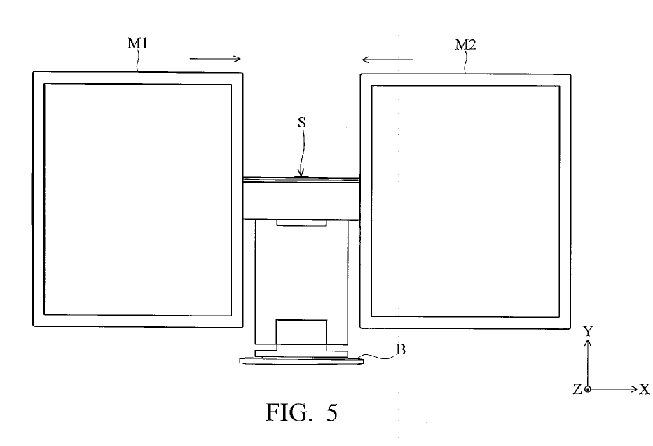

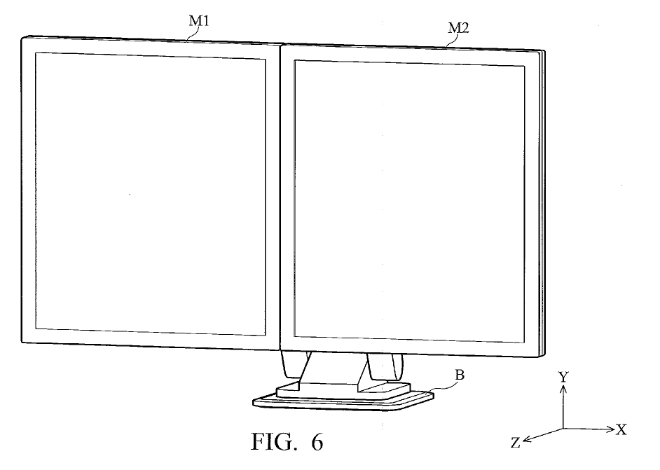

In this embodiment, the first and second displays M1 and M2 are also movable along X axis and rotatable around Z axis. Referring to FIGS. 2-6, the first and second displays M1 and M2 can be moved in opposite directions parallel to X axis and separated from an initial state shown in FIG. 2 to the state shown in FIG. 3. Subsequently, the first and second displays M1 and M2 are rotated clockwise from the transition state of FIG. 4 to FIG. 5. Finally, the first and second displays M1 and M2 are moved to each other as shown in FIG. 6. Here, the first and second displays M1 and M2 of the dual display device are synchronously rotatable and movable between the states shown in FIGS. 2-6, capable of posture adjustment for convenient viewing.

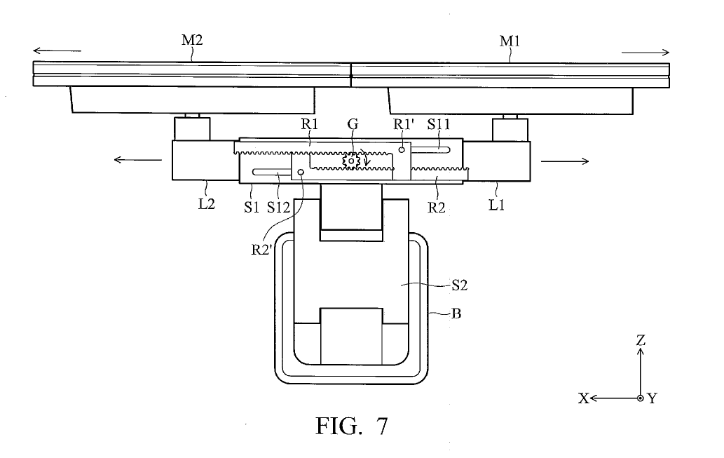

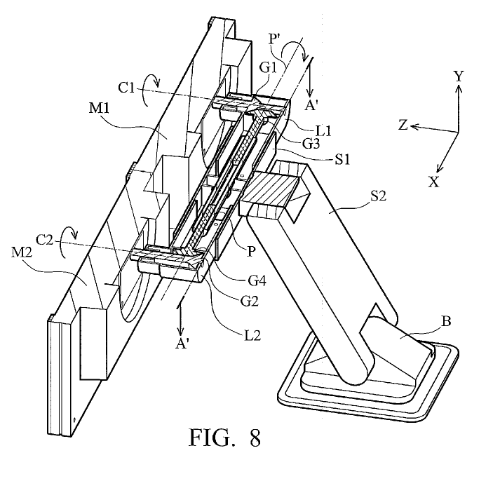

Referring to FIGS. 7 and 8, the dual display device further comprises a translation mechanism (FIG. 7) and a rotary mechanism (FIG. 8) coupled with the translation mechanism for translation and rotation of the first and second displays M1 and M2. In this embodiment, the translation and rotary mechanisms are movably connected to the frame S1, and the first and second displays M1 and M2.

As shown in FIG. 7, the translation mechanism includes a first slider L1, a second slider L2, a central gear G, a first rack R1, and a second rack R2. In this embodiment, the first and second sliders L1 and L2 are substantially L-shaped and movably connected to both ends of the frame S1. Two fasteners R1′ and R2′ are inserted through two longitudinal opening S11 and S12 of the frame S1, respectively, to fix the first and second racks R1 and R2 to the first and second sliding sliders L1 and L2.

The gear G is pivotally disposed on the frame S1 and engaged with the first and second racks R1 and R2. When the gear G rotates and impels the first and second racks R1 and R2, the first and second sliders L1 and L2 are symmetrically moved in opposite directions with respect to the frame S1, and the fasteners R1′ and R2′ slide along the openings S11 and S12, as the arrows indicated in FIG. 7.

Referring to FIG. 8, the rotary mechanism includes a first bevel gear G1 fixed to the first display M1, a second bevel gear G2 fixed to the second display M2, a third bevel gear G3, a fourth bevel gear G4, and a rotary member P. In this embodiment, the first, second, third, and fourth bevel gears G1˜G4 are straight or spiral bevel gears, wherein the first and second bevel gears G1 and G2 are pivotally received in the first and second sliders L1 and L2. Furthermore, the third and fourth bevel gears G3 and G4 are pivotally received in the first and second sliders L1 and L2 and engaged with the first and second bevel gears G1 and G2, respectively.

As shown in FIG. 8, the rotary member P is hollow and pivotally received in the frame S1, wherein the third and fourth bevel gears G3 and G4 are movably received in the rotary member P. When the first display M1 and the first bevel gear G1 rotate around a first axis C1, the rotary member P, the third and fourth bevel gears G3 and G4 are rotated around a central axis P′ of the rotary member P, such that the second display M2 and the second bevel gear G2 are impelled to rotate around a second axis C2. In this embodiment, the first and second axes C1 and C2 are substantially parallel to the Z axis and perpendicular to the central axis P′. It is noted that interference of the first and second displays M1 and M2 during rotation should be prevented by previously separating them from each other, as in the state shown in FIG. 3.

As mentioned above, the third and fourth bevel gears G3 and G4 are movably received in the rotary member P. Hence, when the first and second racks R1 and R2 of the translation mechanism impel the first and second sliders L1 and L2 in opposite directions, the third and fourth bevel gears G3 and G4 slide in opposite directions along the central axis P′, such that interference between the translation and rotary mechanisms is prevented, facilitating flexible posture adjustment of the displays.

Dual display devices are provided according to the embodiments. The dual display device comprises two displays capable of synchronous rotation and translation, facilitating flexible posture adjustment and convenience of usage.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. A dual display device, comprising:
a first display;
a second display;
a support;
a rotary mechanism, pivotally connected to the support and coupled with the first and second displays, wherein the first and second displays are synchronously rotated with respect to the support via the rotary mechanism; and
a translation mechanism, movably connected to the support and coupled with the rotary mechanism,
wherein the first and second displays are symmetrically moved with respect to the support via the translation mechanism.

2. The dual display device of claim 1, the support comprising a frame, the translation mechanism comprising a central gear, a first rack, and a second rack, wherein the central gear is pivotally connected to the frame and engaged with the first and second racks, and when the central gear rotates to impel the first and second racks in opposite directions, the first and second displays are symmetrically moved with respect to the support.

3. The dual display device of claim 2, the rotary mechanism comprising a first bevel gear fixed to the first display, a second bevel gear fixed to the second display, a third bevel gear engaged with the first bevel gear, a fourth bevel gear engaged with the second bevel gear, and a rotary member pivotally received in the frame and movably connected to the first and fourth bevel gears, wherein when the first display and the first bevel gear rotate around a first axis, the rotary member, the third and fourth bevel gears and are rotated around a central axis of the rotary member, and the second display and the second bevel gear are rotated around a second axis.

4. The dual display device of claim 2, the translation mechanism further comprising a first slider and a second slider movably disposed at opposite ends of the frame, wherein the first and second sliders are pivotally connected to the rotary member and fixed to the first and second racks, respectively.

5. The dual display device of claim 4, wherein the first and second sliders are L-shaped.

6. The dual display device of claim 4, the rotary mechanism comprising a first bevel gear fixed to the first display, a second bevel gear fixed to the second display, a third bevel gear engaged with the first bevel gear, a fourth bevel gear engaged with the second bevel gear, and a rotary member pivotally received in the frame and movably connected to the first and fourth bevel gears, wherein when the first display and the first bevel gear rotate around a first axis, the rotary member, the third, and fourth bevel gears are rotated around a central axis of the rotary member, and the second display and the second bevel gear are rotated around a second axis.

7. The dual display device of claim 6, wherein when the first and second racks impel the first and second sliders in opposite directions, the third and fourth bevel gears are moved with respect to the rotary member in opposite directions.

8. The dual display device of claim 6, wherein the first and second axes are substantially perpendicular to the central axis.

9. The dual display device of claim 6, wherein moving directions of the first and second displays are parallel to the central axis.

10. The dual display device of claim 6, wherein the first, second, third, and fourth bevel gears are straight or spiral bevel gears.

11. The dual display device of claim 1, further comprising a base pivotally connected to the support.

12. The dual display device of claim 11, further comprising a connection member pivotally connecting the support and the base.
